(19) United States
(12) Patent Application Publication
(10) Pub. No.: US 2023/0367738 A1
(43) Pub. Date: Nov. 16, 2023

(54) ASIC POWER CONTROL

(71) Applicant: BAE Systems Information and Electronic Systems Integration Inc., Nashua, NH (US)

(72) Inventors: David D. MOSER, Haymarket, VA (US); Daniel L. STANLEY, Warrenton, VA (US); Jennifer KOEHLER, Gainesville, VA (US); Stephen A. CHADWICK, Bristow, VA (US)

(73) Assignee: BAE Systems Information and Electronic Systems Integration Inc., Nashua, NH (US)

(21) Appl. No.: 17/741,915

(22) Filed: May 11, 2022

(51) Int. Cl. G06F 15/78; H01L 29/78

(52) U.S. Cl. CPC G06F 15/7825; G06F 15/7839; H01L 29/785; G06F 2015/763

(57) ABSTRACT

A logic power network provided in an application-specific integrated circuit (ASIC). The ASIC includes a central processor. The ASIC also includes at least one intellectual property (IP) core operatively connected with the central processor and having a set of electrical components provided therein. The ASIC also includes a network-on-chip (NOC) operatively connected with the central processor and the at least one IP core. The ASIC also includes a logic power network operatively connected with the central processor, the at least one IP core and the set of electrical components therein, and the NOC. The logic power network is adapted to control power of the at least one IP core and the set of electrical components provided in the at least one IP Core individually and separately.

### TECHNICAL FIELD

The present disclosure generally relates to application-specific integrated circuits (ASICs). More particularly, the present disclosure relates to ASIC power controls. Specifically, the present disclosure relates to ASIC power controls having logic power networks logically controlling dynamic power to at least one intellectual property (IP) core and electrical components provided in the at least one IP core in ASICs.

### BACKGROUND

Application-specific integrated circuits (hereinafter ASIC) are customized devices and/or components configured for specific uses and optimized for specific tasks. In contrast to general-purpose integrated circuits, ASICs are implemented for particular applications in various industries, including automotive industries, aerospace and aeronautical industries, mobile device industries, medical industries, home automation industries, and other industries of the like. Additionally, ASICs may also provide complex versions that include multiple functions such as microprocessors, peripheral functions, interface functions, and other functions of the like. These complex ASICs may also include intellectual property (IP) cores that are predesigned by a third-party developer for performing predesigned, specific functions. With these components, such complex ASICs must include a power management system that delivers power to each component and network provided on these complex ASICs. However, such power management systems of these ASICs are complex and difficult due to individually controlling power at each component on these ASICs while reducing power dissipation in the ASICs.

To combat these power management system, designers of these ASICs may use power gate devices to control power into individual components like IP cores. However, installation of these power gate devices are rather time consuming and complex due to the number of devices and components provided on these complex ASICs. Generally, designers of these complex ASICs must cut and/or re-arranged power grids of these complex ASICs to allow the power gate to control power to each individual component. In one instance, each IP core of a complex ASIC is separated and isolated on individual power islands on the ASIC so that each IP core is individually controlled by the power gate. In this instance, the designers of these ASICs must also include power isolation buffers between each IP core and/or each electrical component on the ASIC to prevent electrical interference between neighboring and/or adjacent components on the ASIC. Moreover, testing and validating these connections on the ASIC is rather difficult when modeling power in simulation applications. Furthermore, complex ASICs also account for prevention against power leakage driven by certain components provided in ASICs. Specifically, random access memory components (RAMs) provided in IP cores are generally the leading causes in power leakage found in complex ASICs. As such, these power gates must also be integrated with these RAMs in order to prevent power leakage in the ASICs, which ultimately leads to longer build times and complex power systems for these ASICs.

### SUMMARY

The presently disclosed ASIC power control system provides designers of ASICs with the capability of logically controlling components without rearranging and/or reconfiguring the power control systems. The presently disclosed ASIC power control system includes a logic power network that is enabled to logically control the dynamic power of IP cores in the ASIC via a first logic power gate or clock gate. The presently disclosed ASIC power control system also includes a logic power network that is enabled to logically control the power of the electrical components provided in each IP core via a second logic power gate or component power gate. As such, the ASIC power control system disclosed herein addresses some of the inadequacies of previously known techniques and uses of ASIC power control systems.

In one aspect, an exemplary embodiment of the present disclosure may provide an application-specific integrated circuit (ASIC). The ASIC includes a central processor. The ASIC also includes at least one intellectual property (IP) core operatively connected with the central processor, the at least one IP core having a set of electrical components provided therein. The ASIC also includes a network-on-chip (NOC) operatively connected with the central processor and the at least one IP core. The ASIC also includes a logic power network operatively connected with the central processor, the at least one IP core and the set of electrical components therein, and the NOC. The logic power network is adapted to control power of the at least one IP core and the set of electrical components provided in the at least one IP Core individually and separately.

This exemplary embodiment or another exemplary embodiment may further provide that wherein the logic power network comprises: an IP clock gate operatively connected with the at least one IP core; wherein the IP clock gate is configured to control dynamic power of the at least one IP core. This exemplary embodiment or another exemplary embodiment may further provide that wherein the logic power network further comprises: a component power gate operatively connected with the set of electrical components; wherein the component power gate is configured to control power of each electrical component of the set of electrical components. This exemplary embodiment or another exemplary embodiment may further provide that wherein the logic power network further comprises: a first side logic channel operatively connecting the central processor, the at least one IP core, the NOC, and the IP clock gate; wherein the IP clock gate is adapted to control the dynamic power of the at least one IP core between an ON state and an OFF state upon receiving at least one input from the central processor over the first side logic channel. This exemplary embodiment or another exemplary embodiment may further provide that wherein the logic power network further comprises: a second side logic channel operatively connecting the central processor, the at least one IP core, and the component power gate; wherein the component power gate is adapted to control the power of the set of electrical components of the least one IP core between an ON state and an OFF state upon or in response to receiving at least another input from the central processor over second side logic channel. This exemplary embodiment or another exemplary embodiment may further provide a first command output from the central processor to the NOC and the IP clock gate; wherein the IP clock gate activates the at least one IP core between the ON state and the OFF state. This exemplary embodiment or another exemplary embodiment may further provide a second command output from the central processor to the component power gate; wherein component power gate activates the set of electrical components of the at least one IP core between the ON state and the OFF state. This exemplary embodiment or another exemplary embodiment may further provide that wherein the set of electrical components is a set of random-access memory (RAM). This exemplary embodiment or another exemplary embodiment may further provide that wherein the component power gate is configured to operate with fin field-effect transistors.

In another aspect, an exemplary embodiment of the present disclosure may provide a logic power network provided in an application-specific integrated circuit (ASIC). The logic power network includes an IP clock gate operatively connected to at least one IP core of the ASIC. The logic power network also includes a component power gate operatively connected to a set of electrical components of the at least one IP core. The IP clock gate is configured to control dynamic power of the at least one IP core. The component power gate is configured to control power of each electrical component of the set of electrical components.

This exemplary embodiment or another exemplary embodiment may further provide a first side logic channel operatively connecting the IP clock gate with a central processor of the ASIC, the at least one IP core, and a network-on-chip (NOC) of the ASIC; wherein the IP clock gate is adapted to control the dynamic power of the at least one IP core between an ON state and an OFF state upon or in response to receiving at least one input from the central processor over the first side logic channel. This exemplary embodiment or another exemplary embodiment may further provide a second side logic channel operatively connecting the component power gate with the central processor and the at least one IP core; wherein the component power gate is adapted to control the power of the set of electrical components of the least one IP core between an ON state and an OFF state upon or in response to receiving at least another input from the central processor over the second side logic channel. This exemplary embodiment or another exemplary embodiment may further provide a first command output from the central processor to the NOC and the IP clock gate; wherein the IP clock gate is adapted to activate the at least one IP core between the ON state and the OFF state. This exemplary embodiment or another exemplary embodiment may further provide a second command output from the central processor to the component power gate; wherein component power gate activates the set of electrical components of the at least one IP core between the ON state and the OFF state.

In yet another aspect, an exemplary embodiment of the present disclosure may provide a method of controlling power of an application-specific integrated circuit (ASIC). The method comprises steps of: outputting a first command via a central processor of the ASIC; receiving the first command, via a first side logic channel of a logic power network, at an intellectual property (IP) clock gate of the logic power network; receiving the first command, via a second side logic channel of the logic power network, at a component power gate of the logic power network; controlling dynamic power, via the IP clock gate, to at least one IP core; and disabling operation, via the component power gate, to a set of electrical components provided in the at least one IP core from an active state to a dormant state.

This exemplary embodiment or another exemplary embodiment may further provide a step of notifying a network-on-chip (NOC) of the ASIC, via IP clock gate over the first side logic channel, that the dynamic power of the at least one IP core has changed. This exemplary embodiment or another exemplary embodiment may further provide that the step of disabling operation, via the component power gate, to a set of electrical components provided in the at least one IP core includes that the set of electrical components is in the dormant state. This exemplary embodiment or another exemplary embodiment may further provide a step of recording an act of unauthorized access to the at least one IP core via an error unit of the ASIC. This exemplary embodiment or another exemplary embodiment may further provide steps of outputting a second command via the central processor of the ASIC; receiving the second command, via the first side logic channel of the logic power network, at the IP clock gate of the logic power network; controlling dynamic power, via the IP clock gate, to the at least one IP core; and notifying the NOC, via the IP clock gate over the first side logic channel, that the dynamic power of the at least one IP core is ready for use. This exemplary embodiment or another exemplary embodiment may further provide steps of outputting a second command via the central processor of the ASIC; receiving the second command, via the second side logic channel of the logic power network, at the component power gate of the logic power network; and enabling operation, via the component power gate, to the set of electrical components provided in the at least one IP core, wherein the set of electrical components is in the active state at a time prior to disabling operation.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1 (FIG. 1) is a schematic representation of a PRIOR ART intellectual property (IP) core power system having a set of electrical components provided therein.

FIG. 2 (FIG. 2) is a schematic representation of an IP Core having a set of electrical components provided therein with a logic power network in accordance with an aspect of the present disclosure.

FIG. 3 (FIG. 3) is a schematic representation of an application-specific integrated circuit (ASIC) having a set of IP cores with the logic power network in accordance with an aspect of the present disclosure.

FIG. 4 (FIG. 4) is a flow chart for a method of controlling power of an ASIC.

Similar numbers refer to similar parts throughout the drawings.

### DETAILED DESCRIPTION

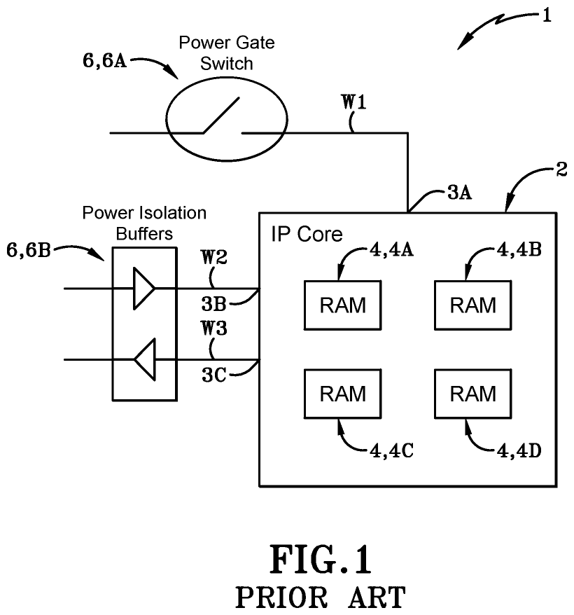

FIG. 1 illustrates a PRIOR ART application-specific integrated circuit (hereinafter “ASIC”) generally referred to as 1. As illustrated herein, ASIC 1 includes at least one semiconductor intellectual property (IP) core or IP core 2 that is a reusable component of logical function enabled to provide an application-specific function in the PRIOR ART ASIC 1 during operation. In the illustrated embodiment, a single IP core 2 is described and illustrated herein. In other exemplary embodiments, any suitable number of IP cores may be provided in an ASIC for specific applications.

Still referring to FIG. 1, the IP core 2 of the PRIOR ART ASIC 1 includes at least one power terminal 3 to enabling power to the IP core 2 during operation. In the illustrated embodiment, the IP core 2 includes a first power terminal 3A and a second power terminal 3B to enabling power to the IP core 2 during operation; such use and purpose of each power terminal 3A, 3B is described in more detail below.

Still referring to FIG. 1, the IP core 2 of the PRIOR ART ASIC 1 includes a set of electrical components 4 provided inside of the IP core 2. The set of electrical components 4 of the IP core 2 include electrical components that are used to perform at least one application-specific function required by the IP core 2 in the PRIOR ART ASIC 1. In the illustrated embodiment, first, second, third, and fourth electrical components 4A, 4B, 4C, 4D are provided in the IP core 2 where each of the first, second, third, and fourth electrical components 4A, 4B, 4C, 4D are random access memory (RAM) components. In other exemplary embodiments, any suitable number of electrical components and any suitable electrical component may be used in an IP core for at least one application-specific function in a PRIOR ART ASIC. Additionally, each electrical component of the set of electrical components 4A, 4B, 4C, 4D is provide on a power island that is separate and independent from another power island one another in an application-specific configuration for the PRIOR ART ASIC 1.

Still referring to FIG. 1, the IP core 2 of the PRIOR ART ASIC 1 includes a hardwire power gating network 6 that controls the power to the IP core 2 and the set of electrical components 4 provided therein. The power gating network 6 generally includes a power gate switch 6A that is operatively connected with the IP core 2 as a whole to control power of the IP core 2 between an ON state and an OFF state. In other words, the power gate switch 6A controls all power at the IP core 2. The power gating network 6 also generally includes power isolation buffers 6B that are operatively connected with and/or straddle each electrical component of the set of electrical components 4. Such connections between the set of electrical components 4 and the power isolation buffers 6B require a designer of the PRIOR ART ASIC 1 to configure a power grid of the PRIOR ART ASIC 1 where power of the set of electrical components 4 is separate and isolated from another set of electrical component 4 of another IP core 2 provided in the PRIOR ART ASIC 1.

Generally, the power gate switch 6A is configured separately and independently of the IP core 2 which causes issues to meet the Unified Power Format (hereinafter “UPF”) flow. Such issues occur with PRIOR ART ASIC 1 because the power gate switch 6A needs to be hardwired with each electrical component of the set of electrical components 4 based on the application-specific configuration of the electrical components 4. Specifically, a plurality of electrical connections is electrically connected to the set of electrical components 4 to control power of the set of electrical components 4 via the power gate switch 6A and to isolate power at each electrical component of the set of electrical components 4 from another set of electrical component of another IP core provided in the PRIOR ART ASIC 1 via the power isolation buffers 6B. As such, the plurality of electrical connections between the power gating network 6 and the set of electrical components 4 become difficult and time consuming due to the physical design and arrangement of the set of electrical components 4 provided in the IP core 2.

Once the PRIOR ART ASIC 1 power systems are complete, designers of these PRIOR ART ASIC 1 power systems must run validation procedures and/or applications to determine if the reconfigured power connections provided suitable power to each IP core and/or electrical components connected in the PRIOR ART ASIC 1 power systems. Generally, designers must create new simulation procedures when these power gate switches 6A are connected with the IP cores 2 due to the new power system configuration and design in the PRIOR ART ASIC 1. As such, the creation of these new simulation procedures cause greater build times and testing times.

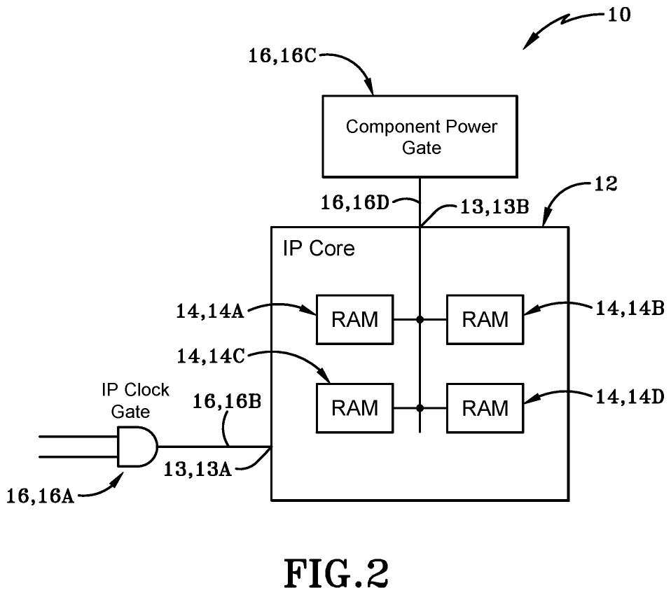

FIG. 2 illustrates a ASIC 10 in accordance with an aspect of the present disclosure. ASIC 10 includes at least one semiconductor IP core or IP core 12 that is a reusable component of logical function enabled to provide an application-specific function in the ASIC 10 during operation. In the illustrated embodiment, a single IP core 12 is described and illustrated herein. In other exemplary embodiments, any suitable number of IP cores may be provided in an ASIC for a specific application.

Still referring to FIG. 2, the IP core 12 of ASIC 10 includes at least one power terminal 13 to enabling power to the IP core 12 during operation. In the illustrated embodiment, the IP core 12 includes a first power terminal 13A and a second power terminal 13B to enabling power to the IP core 12 during operation; such use and purpose of each terminal 13A, 13B is described in more detail below.

Still referring to FIG. 2, the IP core 12 of ASIC 10 includes a set of electrical components 14 provided inside of the IP core 12. The set of electrical components 14 of the IP core 12 include electrical components that are used to perform at least one application-specific function required by the IP core 12 in ASIC 10. In the illustrated embodiment, first, second, third, and fourth electrical components 14A, 14B, 14C, 14D are provided in the IP core 12 where each of the first, second, third, and fourth electrical components 14A, 14B, 14C, 14D are random access memory (RAM) components. In other exemplary embodiments, any suitable number of electrical components and any suitable electrical component may be used in an IP core for at least one application-specific function in an ASIC. Additionally, each electrical component of the set of electrical components is separate and independent of one another in an application-specific configuration for the ASIC 1.

As provided herein, each electrical component of the set of electrical components 14 includes a preconfigured power system that is isolated from surrounding and/or peripheral electrical components provided therein. As such, each electrical component of the set of electrical components 14 includes power gate switches, power isolation buffers, and other suitable power control components for enabling the electrical component to switch between an ON state and an OFF state. For example, the first, second, third, and fourth electrical components 14A, 14B, 14C, 14D are RAMs that include power gate switches, power isolation buffers, and other suitable power control components for enabling the RAMs to switch between different operation modes and/or settings (e.g., sleep mode, hibernation mode, etc.) or switch between an ON state and an OFF state. Moreover, the IP core may use fin field-effect (FinFet) transistor technology to reduce the overall power leakage from the RAMs 14A, 14B, 14C, 14D and other electrical components provided in the IP core 2. While such power technology is available, these RAMs 14A, 14B, 14C, 14D still power leakage.

Still referring to FIG. 2, ASIC 1 includes a logic power network 16 that is operably engaged with the IP core 2 and a power grid (not illustrated) of ASIC 1. The logic power network 16 separately controls the power to the IP core 12 and the set of electrical components 14 provided therein to reduce power dissipation and to reduce power leakage. As described in more detail below, the logic power network 16 is configured to remove power at both the IP core 12 power level and at the set of electrical components 14 power level without complex physical hardwiring as compared to the PRIOR ART ASIC 1. In other words, the logic power network 16 is configured to logically control power at both the IP core 12 power level and at the set of electrical components 14 power level via on-board applications on the preconfigured ASIC 10, which is described in more detail below.

The logic power network 16 includes a first logic power gate or IP clock gate 16A (hereinafter “clock gate”) logically connected with the IP core 12 for controlling dynamic power into the IP core 12. Specifically, the clock gate 16A logically connects with the IP core 12 via a first side logic channel 16B. During operation, the clock gate 16A is adapted to control and activate the dynamic power and/or clock signal of the IP core 12 provided from the power grid of the ASIC 10. As such, the clock gate 16A is configured to activate the dynamic power of the IP core 12 between an ON state and an OFF state upon commands from a central processor of ASIC 10, which is described in more detail below.

The inclusion of the clock gate 16A with the IP core 12 of ASIC 10 is considered advantageous at least because the clock gate 16A completely controls the dynamic power of the IP core 12 without reconfiguring or rearranging the power grid of the ASIC 10 as compared to the PRIOR ART ASIC 1 described above. In other words, the clock gate 16A is configured to logically control the dynamic power of the IP core 12 via on-board applications and/or components provide in the preconfigured ASIC 10. As such, the power grid of the ASIC 10 remains unchanged and logically controls the dynamic power of the IP core 12 by switching the dynamic control between the ON state and the OFF state.

Still referring to FIG. 2, the logic power network 16 also includes a second logic power gate or a component power gate 16C operatively connected with the set of electrical components 14 of the IP core 12 via a second side logic channel 16D. Specifically, the component power gate 16C operatively connects with the second power terminal 13B of the IP core 12 via the second side logic channel 16D. The component power gate 16C logically connects with each electrical component of the set of electrical components 14 provided in the IP core 12 through programs and/or applications preconfigured with and integrated into the set of electrical components 14. Upon these connections, the component power gate 16C is able to communicate with each electrical component of the set of electrical components 14 via logic controls to activate one or all of the electrical components in the set of electrical components 14. Additionally, the component power gate 16C is a standardized bus that enables a central processor or other similar component of the ASIC 10 to communicate with the electrical components in the set of electrical components 14 to be activated between the ON state and the OFF state, which is described in more detail below.

As provided herein, the component power gate 16C is enabled to communicate with the first, second, third, and fourth RAMs 14A, 14B, 14C, 14D during operation. Per the power systems preconfigured inside of these RAMs 14A, 14B, 14C, 14D, the component power gate 16C is configured to control these power systems to individually and/or collectively activate these RAMs 14A, 14B, 14C, 14D between power modes and/or between the ON state and the OFF state. Such communication between the component power gate 16C and the first, second, third, and fourth RAMs 14A, 14B, 14C, 14D is considered advantageous at least because the component power gate 16C is able to prevent leakage driven by the RAMs 14A, 14B, 14C, 14D during powering down operations.

The component power gate 16C is considered advantageous at least because the component power gate 16C is program-agnostic in that the component power gate 16C may be used with various programs and/or applications provided with the set of electrical components 14 in the IP core 12. In other words, the component power gate 16C is adapted to send abstract and/or agnostic signals to various sets of electrical components in various IP cores in various ASIC power systems. As such, the component power gate 16C is modular and may be used with various ASIC power systems without modifying the preconfigured ASIC power systems. With such modularity, the designers of these ASIC power systems may reuse and repurpose the electrical components in IP cores for other applications due to the electrical components be logically controlled by the component power gate 16C.

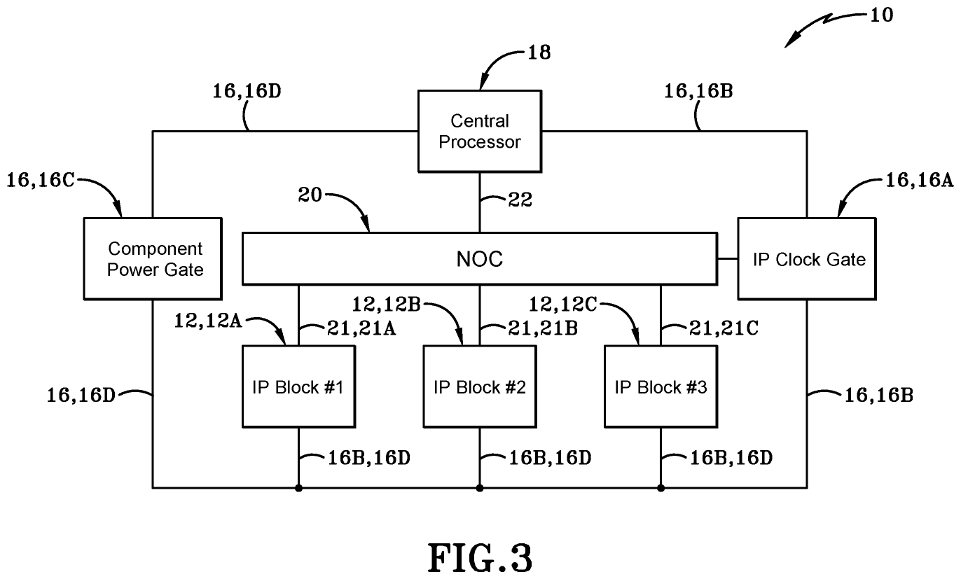

Referring to FIG. 3, ASIC 10 also includes a central processor or processor 18. The central processor 18 may be any suitable central processor 18 for a desired application needed and created for the ASIC 10. The central processor 18 is operatively connected with the logic power network 16. Specifically, the central processor 18 is operatively connected with the clock gate 16A via the first side logic channel 16B, and the central processor 18 is operatively connected with the component power gate 16C via the second side logic channel 16D. As described in more detail below, the central processor 18 is configured to send command(s) and/or signals to one or both of the clock gate 16A and the component power gate 16C for activating the dynamic power of at least one IP core 12 and activating the power of at least one electrical component of the set of electrical components 14 inside of the at least one IP core 12.

Still referring to FIG. 3, ASIC 10 also includes a network on a chip or a chip-on-network (NOC) device. The NOC 20 may be any suitable NOC for a desired application needed and created for the ASIC 10. As illustrated in FIG. 3, the NOC 20 is operatively connected with the logic power network 16 and the central processor 18 individually and via the first side logic channel 16B. Specifically, the NOC 20 is operatively connected with the clock gate 16A of the logic power network 16 and the central processor 18 via the first side logic channel 16B and via individual connections. The NOC 20 is also operatively connected with at least one IP core 12 via electrical connections 21. In the illustrated embodiment, the NOC 20 is operatively connected with a first IP core 12A via a first electrical connection 21A, a second IP core 12B via a second electrical connection 21B, and a third IP core 12C via a third electrical connection 21C in the ASIC 10. In other exemplary embodiments, any suitable number of IP cores may be operatively connected with a NOC based on the desired application and functions of an ASIC. The NOC 20 is also independent from the component power gate 16C of the logic power network 16 where the second side logic channel 16D is free from connecting with the NOC 20. The NOC 20 is also operatively connected with the central processor 18 via an electrical connection 22 separate from the logic power network 16.

Having now described the components and networks of the ASIC 10, a method of using the ASIC 10 is described in more detail below.

In a first use, the central processor 18 is able to switch dynamic power to at least one IP core 12 from the ON state to the OFF state via the logic power network provided in the ASIC 10. During this use, the central processor 18 sends a first command to the clock gate 16A over the first side logic channel 16B to switch dynamic power of the at least one IP core 12 from the ON state to the OFF state. In this example, the first command sent from the central processor 18 to the clock 16A is commanding the clock gate 16A to switch the dynamic power of the first IP core 12A from the ON state to the OFF state. Upon receiving this first command, the clock gate 16A is enabled to disable the dynamic power of the first IP core 12 by deactivating the dynamic power of the first IP core 12 from the ON state to the OFF state. As described above, the clock gate 16A of the logic power network 16 is configured to logically control the dynamic power to each and every IP core 12A, 12B, 12C provided in the ASIC 10.

In other exemplary embodiments, the clock gate 16A is able to logically control a specific IP core 12 or to all IP cores 12 by disabling and/or deactivating dynamic power upon at least one command given by the central processor 18.

Once the first command is sent from the central processor 18 to the clock gate 16A, the central processor 18 notifies the NOC 20 via a first notification that the dynamic power of the first IP core 12 is provided in the OFF state prior to, simultaneously to, or subsequent to the clock gate 16A logically performing the operation. Once the NOC 20 is notified, the NOC 20 will logically record this notification that the first IP core 12A is provided in the OFF state. Such record of the first IP core 12A may be used for security when a user or other device tries to access the first IP core 12A in the OFF state. If such unauthorized action occurs, the unauthorized action will be recorded in an on-board error system of the ASIC 10 to record such unauthorized or invalid access into the first IP core 12.

Moreover, the central processor 18 may also send the first command to the logic power network 16 to provide at least one electrical component of the set of electrical components 14 of at least one IP core 12 in the OFF state. Specifically, the central processor 18 may send the first command to the component power gate 16C, via the second side logic channel 16D, to provide at least one electrical component of the set of electrical components 14 of at least one IP core 12 in the OFF state. In this example, the central processor 18 sends the first command to the component power gate 16C to provide at least one electrical component of the set of electrical components 14 of the first IP core 12A in the OFF state. Once received, the component power gate 16C provides at least one electrical component or all of the electrical components of the set of electrical components 14 in the OFF state. Upon this command, the central processor 18 may send any suitable number of commands to the component power gate 16C for providing any electrical component of a set of electrical components of at least another IP core in an OFF state.

In other exemplary embodiments, a command sent by a central processor may be any suitable command for controlling a set of electrical component provided in an IP core of an ASIC. In the illustrated embodiment, the central processor 18 is adapted to send commands to the component power gate 16C, via the second side logic channel 16D, to provide at least one RAM of the set of RAMs 14 of the first IP core 12 in a specific state that is preconfigured into the specific RAM instead of an OFF state. In one instance, the central processor 18 is adapted to send a command to the component power gate 16C, via the second side logic channel 16D, to provide at least one RAM of the set of RAMs 14 of the first IP core 12 in a hibernation mode or a dormant state that is preconfigured into the specific RAM to instead of an OFF state. In another instance, the central processor 18 is adapted to send a command to the component power gate 16C, via the second side logic channel 16D, to provide at least one RAM of the set of RAMs 14 of the first IP core 12 in a hibernation mode and/or a frozen dormant state that is preconfigured into the specific RAM instead of an OFF state.

Once at least one IP core 12 is provided in the OFF state via the clock gate 16A and/or the component power gate 16C, the ASIC 10 may then command the at least one IP core 12 to the ON state for various operational reasons. As such, the following method of use details the logic power network 16 providing dynamic power to at least one IP core 12 and providing the electrical components 14 of at least one IP core 12 from the OFF state to the ON state.

Upon this operation, the central processor 18 may send a second command to the logic power network 16 to provide at least one electrical component of the set of electrical components 14 of at least one IP core 12 from the OFF state to the ON state. Specifically, the central processor 18 may send the first command to the component power gate 16C, via the second side logic channel 16D, to provide at least one electrical component of the set of electrical components 14 of at least one IP core 12 in the ON state. In this example, the central processor 18 sends the first command to the component power gate 16C to provide at least one electrical component of the set of electrical components 14 of the first IP core 12A from the OFF state to the ON state. Once received, the component power gate 16C provides at least one electrical component or all of the electrical components of the set of electrical components 14 from the OFF state to the ON state. Upon this command, the central processor 18 may send any suitable number of commands to the component power gate 16C for providing any electrical component of a set of electrical components of at least another IP core from an OFF state to an ON state.

In other exemplary embodiments, a command sent by a central processor may be any suitable command for controlling a set of electrical components provided in an IP core of an ASIC. In the illustrated embodiment, the central processor 18 is adapted to send commands to the component power gate 16C, via the second side logic channel 16D, to provide at least one RAM of the set of RAMs 14 of the first IP core 12 in a specific state that is preconfigured into the specific RAM instead of an OFF state. In one instance, the central processor 18 is adapted to send a command to the component power gate 16C, via the second side logic channel 16D, to provide at least one RAM of the set of RAMs 14 of the first IP core 12 from a hibernation mode and/or a dormant state that is preconfigured into the specific RAM to an ON state or active state. In another instance, the central processor 18 is adapted to send a command to the component power gate 16C, via the second side logic channel 16D, to provide at least one RAM of the set of RAMs 14 of the first IP core 12 in a hibernation mode and/or a dormant state that is preconfigured into the specific RAM to an ON state or active state.

The central processor 18 is then able to switch dynamic power to at least one IP core 12 from the OFF state to the ON state via the logic power network provided in the ASIC 10. During this use, the central processor 18 sends the second command to the clock gate 16A over the first side logic channel 16B to switch dynamic power of the at least one IP core 12 from the OFF state to the ON state. In this example, the second command sent from the central processor 18 to the clock 16A is commanding the clock gate 16A to switch the dynamic power of the first IP core 12A from the OFF state to the ON state. Upon receiving this second command, the clock gate 16A enables the dynamic power of the first IP core 12 by activating the dynamic power of the first IP core 12 from the OFF state to the ON state. As described above, the clock gate 16A of the logic power network 16 is configured to logically control the dynamic power to each and every IP core 12A, 12B, 12C provided in the ASIC 10.

In other exemplary embodiments, the clock gate 16A is able to logically control a specific IP core 12 or all IP cores 12 by enabling and/or activating dynamic power upon at least one command given by the central processor 18.

Once the second command is sent from the central processor 18 to the clock gate 16A, the central processor 18 notifies the NOC 20 via a second notification that the dynamic power of the first IP core 12 is provided in the ON state subsequent to the clock gate 16A logically performing the operation. In this embodiment, the second notification sent from the central processor 18 to the NOC 20 may be delayed after the clock gate 16A provides the first IP core 12 at the ON state to allow the first IP core 12A to be available for operation. In other words, the second notification sent from the central processor 18 to the NOC 20 may be delayed to allow the first IP core 12 to boot up and be provided in a state to operate. Additionally, the second notification sent from the central processor 18 to the NOC 20 may be delayed after the component power gate 16C provides at least one or all of the electrical components in the set of electrical components 14 of the first IP core 12 from the OFF state to the ON state. Such delay allows the at least one or all of the electrical components in the set of electrical components 14 of the first IP core 12 to boot up and be provided in a state to operate. Once the first IP core 12A is booted and ready for use, the NOC 20 will be notified by one of both of the clock gate 16A and the central processor 18.

In other exemplary embodiment, the logic power network 16 and the central processor 18 may continuously provide one or all of the IP cores 12 in either the ON state or the OFF state depending upon operation of ASIC 10.

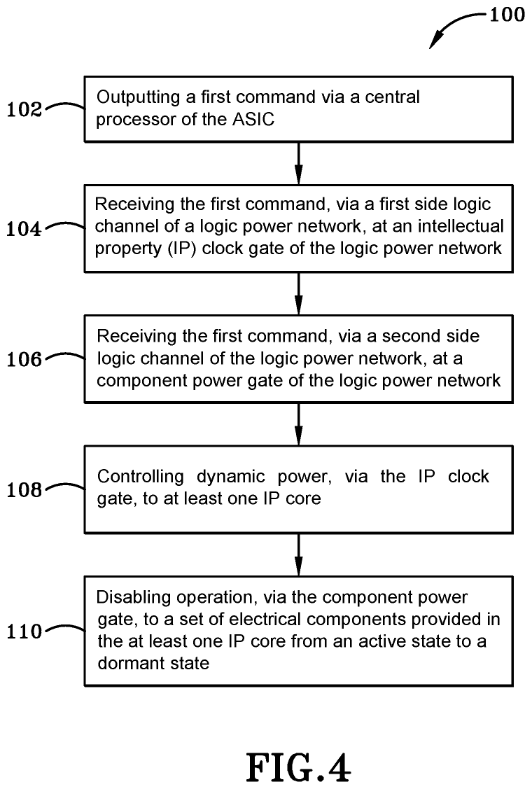

FIG. 4 illustrates a method 100 of controlling power of an application-specific integrated circuit (ASIC). An initial step 102 of method 100 comprises outputting a first command via a central processor of the ASIC. Another step 104 of method 100 comprises receiving the first command, via a first side logic channel of a logic power network, at an intellectual property (IP) clock gate of the logic power network. Another step 106 of method 100 comprises receiving the first command, via a second side logic channel of the logic power network, at a component power gate of the logic power network. Another step 108 of method 100 comprises controlling dynamic power, via the IP clock gate, to at least IP core. Another step 110 of method 100 comprises disabling operation, via the component power gate, to a set of electrical components provided in the at least one IP core from an active state to a dormant state.

In other exemplary embodiments, method 100 may include additional and/or optional steps. An optional step may include notifying a network-on-chip (NOC) of the ASIC, via IP clock gate over the first side logic channel, that the dynamic power of the at least one IP core has changed. An optional step may include that wherein the step of disabling operation, via the component power gate, to a set of electrical components provided in the at least one IP core includes that the set of electrical components is in the dormant state. An optional step may include recording an act of unauthorized access to the at least one IP core via an error unit of the ASIC. Optional steps may include outputting a second command via the central processor of the ASIC; receiving the second command, via the first side logic channel of the logic power network, at the IP clock gate of the logic power network; controlling dynamic power, via the IP clock gate, to the at least one IP core; and notifying the NOC, via the IP clock gate over the first side logic channel, that the dynamic power of the at least one IP core is ready for use. Optional steps may include outputting a second command via the central processor of the ASIC; receiving the second command, via the second side logic channel of the logic power network, at the component power gate of the logic power network; and enabling operation, via the component power gate, to the set of electrical components provided in the at least one IP core, wherein the set of electrical components is in the active state at a time prior to disabling operation.

As described herein, aspects of the present disclosure may include one or more electrical, pneumatic, hydraulic, or other similar secondary components and/or systems therein. The present disclosure is therefore contemplated and will be understood to include any necessary operational components thereof. For example, electrical components will be understood to include any suitable and necessary wiring, fuses, or the like for normal operation thereof. Similarly, any pneumatic systems provided may include any secondary or peripheral components such as air hoses, compressors, valves, meters, or the like. It will be further understood that any connections between various components not explicitly described herein may be made through any suitable means including mechanical fasteners, or more permanent attachment means, such as welding or the like. Alternatively, where feasible and/or desirable, various components of the present disclosure may be integrally formed as a single unit.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. An application-specific integrated circuit (ASIC), comprising:
a central processor;
at least one intellectual property (IP) core operatively connected with the central processor, the at least one IP core having a set of electrical components provided therein;
a network-on-chip (NOC) operatively connected with the central processor and the at least one IP core; and
a logic power network operatively connected with the central processor, the at least one IP core and the set of electrical components therein, and the NOC;
wherein the logic power network is adapted to control power of the at least one IP core and the set of electrical components provided in the at least one IP Core individually and separately.

2. The ASIC of claim 1, wherein the logic power network comprises:
an IP clock gate operatively connected with the at least one IP core;
wherein the IP clock gate is configured to control dynamic power of the at least one IP core.

3. The ASIC of claim 2, wherein the logic power network further comprises:
a component power gate operatively connected with the set of electrical components;
wherein the component power gate is configured to control power of each electrical component of the set of electrical components.

4. The ASIC of claim 3, wherein the logic power network further comprises:
a first side logic channel operatively connecting the central processor, the at least one IP core, the NOC, and the IP clock gate;
wherein the IP clock gate is adapted to control the dynamic power of the at least one IP core between an ON state and an OFF state upon receiving at least one input from the central processor over the first side logic channel.

5. The ASIC of claim 4, wherein the logic power network further comprises:
a second side logic channel operatively connecting the central processor, the at least one IP core, and the component power gate;
wherein the component power gate is adapted to control the power of the set of electrical components of the least one IP core between an ON state and an OFF state upon or in response to receiving at least another input from the central processor over second side logic channel.

6. The ASIC of claim 5, further comprising:
a first command output from the central processor to the NOC and the IP clock gate;
wherein the IP clock gate activates the at least one IP core between the ON state and the OFF state.

7. The ASIC of claim 6, further comprising:
a second command output from the central processor to the component power gate;
wherein component power gate activates the set of electrical components of the at least one IP core between the ON state and the OFF state.

8. The ASIC of claim 1, wherein the set of electrical components is a set of random-access memory (RAM).

9. The ASIC of claim 3, wherein the component power gate is configured to operate with fin field-effect transistors.

10. A logic power network provided in an application-specific integrated circuit (ASIC), comprising:
an IP clock gate operatively connected to at least one IP core of the ASIC; and
a component power gate operatively connected to a set of electrical components of the at least one IP core;
wherein the IP clock gate is configured to control dynamic power of the at least one IP core; and
wherein the component power gate is configured to control power of each electrical component of the set of electrical components.

11. The logic power network of claim 10, further comprising:
a first side logic channel operatively connecting the IP clock gate with a central processor of the ASIC, the at least one IP core, and a network-on-chip (NOC) of the ASIC;
wherein the IP clock gate is adapted to control the dynamic power of the at least one IP core between an ON state and an OFF state upon or in response to receiving at least one input from the central processor over the first side logic channel.

12. The logic power network of claim 11, further comprising:
a second side logic channel operatively connecting the component power gate with the central processor and the at least one IP core;
wherein the component power gate is adapted to control the power of the set of electrical components of the least one IP core between an ON state and an OFF state upon or in response to receiving at least another input from the central processor over the second side logic channel.

13. The logic power network of claim 12, further comprising:
a first command output from the central processor to the NOC and the IP clock gate;
wherein the IP clock gate is adapted to activate the at least one IP core between the ON state and the OFF state.

14. The logic power network of claim 13, further comprising:
a second command output from the central processor to the component power gate;
wherein component power gate activates the set of electrical components of the at least one IP core between the ON state and the OFF state.

15. A method of controlling power of an application-specific integrated circuit (ASIC), comprising steps of:
outputting a first command via a central processor of the ASIC;
receiving the first command, via a first side logic channel of a logic power network, at an intellectual property (IP) clock gate of the logic power network;
receiving the first command, via a second side logic channel of the logic power network, at a component power gate of the logic power network;
controlling dynamic power, via the IP clock gate, to at least one IP core; and
disabling operation, via the component power gate, to a set of electrical components provided in the at least one IP core from an active state to a dormant state.

16. The method of claim 15, further comprising:
notifying a network-on-chip (NOC) of the ASIC, via IP clock gate over the first side logic channel, that the dynamic power of the at least one IP core has changed.

17. The method of claim 15, wherein the step of disabling operation, via the component power gate, to a set of electrical components provided in the at least one IP core includes that the set of electrical components is in the dormant state.

18. The method of claim 15, further comprising:
recording an act of unauthorized access to the at least one IP core via an error unit of the ASIC.

19. The method of claim 16, further comprising:
outputting a second command via the central processor of the ASIC;
receiving the second command, via the first side logic channel of the logic power network, at the IP clock gate of the logic power network;
controlling dynamic power, via the IP clock gate, to the at least one IP core; and
notifying the NOC, via the IP clock gate over the first side logic channel, that the dynamic power of the at least one IP core is ready for use.

20. The method of claim 16, further comprising:
outputting a second command via the central processor of the ASIC;
receiving the second command, via the second side logic channel of the logic power network, at the component power gate of the logic power network; and
enabling operation, via the component power gate, to the set of electrical components provided in the at least one IP core, wherein the set of electrical components is in the active state at a time prior to disabling operation.
